(19) United States
(12) Patent Application Publication
(10) Pub. No.: US 2021/0337681 A1
(43) Pub. Date: Oct. 28, 2021

(54) VENTILATION DEVICE FOR HEAT ESCAPE

(71) Applicant: Teknologisk Institut, Taastrup (DK)

(72) Inventors: Per Black, Ringsted (DK); Peter Vorup, Hedehusene (DK)

(21) Appl. No.: 16/610,257

(22) PCT Filed: May 4, 2018
(86) PCT No.: PCT/EP2018/061474

§ 371 Date: Nov. 21, 2019

(30) Foreign Application Priority Data
May 4, 2017 (DK) PA 2017 00284

(51) Int. Cl. H05K 5/02; H05K 7/20

(52) U.S. Cl. CPC H05K 5/0213; H05K 7/20136

(57) ABSTRACT

Described herein is a ventilation device for admitting air ventilation of a cabinet and preventing liquid passing from outside to inside of the cabinet, the ventilation device comprises a casing capable of being mounted in front of at least one cabinet opening of a cabinet, where the casing comprises at least one casing opening, a tube with a collar, where the tube is mounted on the casing and covering the at least one casing opening, and a cap covering the collar and leaving distance between the cap and the collar making it capable for air to pass between the cap and the collar.

### CROSS-REFERENCES

This application is a national stage entry of PCT Application No. PCT/EP2018/061474, filed 4 May 2018, and entitled “VENTILATION DEVICE FOR HEAT ESCAPE.” This application claims the benefit of Denmark Patent Application No. PA 2017 00284, filed 4 May 2017, and entitled “VENTILATION DEVICE FOR HEAT ESCAPE WHICH PREVENTS ENTRANCE OF LIQUID INTO SYSTEMS.” Each of these applications is incorporated by reference in its entirety.

### FIELD OF THE DISCLOSURE

The present disclosure relates to a ventilation device for heat escape from a system or cabinet, which ventilation device is suitable to be used in systems cleaned by liquids under high pressure, where the ventilation device prevents liquid from entering the system, and/or the ventilation device catches liquid droplets, which have passed the outer part of the ventilation device.

### BACKGROUND

Prior art describes different kinds of ventilation devices for heat escape without having liquid to enter the device.

U.S. Pat. No. 6,015,444 describes an apparatus and system for venting a transmission, which provides a transmission breather allowing pressure equalization between the interior and exterior of the transmission, while reducing or eliminating fluid expulsion from the transmission. The breather includes a standpipe, a bowl having a first end secured to the standpipe and at least one aperture, a shroud secured to the standpipe, and a filter disposed between the bowl and the standpipe. The standpipe has a first end, a second end and an intermediate portion extending axially between the first and second ends. The second end of the standpipe has at least one surface for transmitting torque to the standpipe to enable the breather to be top drivable to facilitate installation and removal of the breather with the transmission. The intermediate portion has an axially extending central passage and at least one radially extending passage. The shroud restricts the entry of external contaminants into the transmission through the breather. Air, transmission fluid, mist, and vapor flow through the passages of the standpipe and through the filter which captures the fluid, mist and vapor while allowing filtered air to be vented to the environment through the at least one aperture. The filter facilitates coalescence of the transmission fluid which is returned to the transmission via the passages in the standpipe.

U.S. Pat. No. 6,447,565 describes a transmission vent assembly, that includes an apparatus having a central, internal passage extending through there. The internal passage has a larger diameter portion defining a pocket. A filter is disposed in the pocket to condense and return fluid to the transmission through the internal passage. The apparatus includes a shoulder adjacent the upper surface, and a double lead thread initiating at the shoulder and terminating at a lower end. The assembly further includes a cup-shaped cap, press fittingly disposed over the apparatus. The cap and shoulder define an annular cavity and the cap and the double lead thread define first and second threaded passages. The cap includes an outward impression in the closed end which cooperates with the upper surface of the apparatus to define a connecting passage. Two bi-directional air flow paths extend between the transmission and the atmosphere through the internal passage, connecting air passage, annular air cavity, and each of the two threaded passages.

EP 2037154 describes an air ventilation device with a channel connecting a housing inner area with the environment. Another channel is opened at two ends for the environment, so that the channel is through-flowable by the washing medium. The former channel flows transversally in the latter channel, running in the area of a point of constriction. The former channel comprises an air ventilation channel, a collecting space and a connecting channel.

There is a need for simple ventilation devices that can be used for industrial machinery, and especially for industrial machinery frequently exposed to intensive cleaning, such as by high-pressure washing. The ventilation device should preferably avoid liquids or moist from entering the machine, as electrical component may be damaged by the liquid.

### SUMMARY

The ventilation device described herein is a cost-effective solution to recurrent ventilation problems, e.g. in food industry machinery and measuring cabinets producing excess heat, for which it is crucial to maintain internal temperatures below a critical level, where internal machine mechanics and electronic components are at risk of being damaged.

Disclosed herein is a ventilation device for admitting air ventilation of a cabinet, and preventing liquid passing from outside to inside of the cabinet. The ventilation device of the present disclosure comprises: a casing capable of being mounted in front of a cabinet opening of a cabinet, the casing comprising one or more casing openings; a tube with a collar, where the tube is mounted on the casing, and covering a casing opening; and a cap covering the collar, and leaving distance between the cap and the collar making it capable for air to pass between the cap and the collar.

When washing the cabinet, e.g. by high pressure water, and optionally using a detergent, e.g. as foam, the ventilation device as described herein is capable of being washed as the remaining part of the cabinet without water entering the cabinet. The air flow through the ventilation device is winding leaving water and water drops behind in the outermost part of the ventilation device if entering the ventilation device at all.

The casing of the ventilation device may further comprise: a front part with at least one casing opening; and casing walls connected to the front part, where the casing walls result in a distance between the cabinet wall and the front part, when the casing is mounted on a cabinet.

The volume between the outer wall of the cabinet and the inner wall of the front part of the casing may be empty space allowing a distance between a casing opening and a cabinet opening which is for air flow. A dust filter may be located in this volume and preferably as close to the cabinet opening as possible reducing the risk of water e.g. moist reaching the dust filter.

The casing may further comprise at least one liquid outlet preferably in a casing wall located in the bottom part of the casing wall when the casing is mounted on a cabinet. At least one cover may be located above the liquid outlet covering the liquid outlet. If droplets enter the ventilation device e.g. by circumventing the cap and collar and entering through the tube during a washing process such droplets are drained off through the liquid outlet. If water enters the ventilation device through the liquid outlet during a washing process, the cover located above the liquid outlet stops the water and the water is then drained off through the liquid outlet.

The ventilation device is preferably constructed of a material with is liquid tight, such as stainless steel, which is also approved for food and feed production processes.

The ventilation device, as described herein, may be for passive ventilation, however, a fan may also be located at the cabinet opening, and determine the air flow direction through the ventilation device.

The present disclosure is also related to a machine with at least one ventilation device as described herein. Preferably such a machine has two ventilation devices, which preferably are located on vertical cabinet walls. The ventilation may be by passive ventilation through both ventilation devices or a fan may be connected to one or both ventilation devices determining the air flow direction through each ventilation device. If two ventilation devices are located on a machine and a fan is connected to each ventilation device, the air flow direction is preferably out of the cabinet for one ventilation device and into the cabinet for the other ventilation device, hereby increasing the ventilation of the cabinet.

The machine with a ventilation device as described herein is preferably a machine used in the food or feed industry requiring thorough washing.

The present disclosure further relates to use of the ventilation device described herein such as for cooling a machine or a cabinet. Such a machine or cabinet may be a machine used in the food or feed industry.

### BRIEF DESCRIPTION OF THE DRAWINGS

The present disclosure is further illustrated by reference to the accompanying drawings, in which:

FIG. 1 illustrates the front of a ventilation device;

FIG. 2 shows a perspective drawing of a ventilation device;

FIG. 3 illustrates a side view of a ventilation device;

FIGS. 4A and 4B show a vertical cross-sectional view of a ventilation device mounted on a cabinet;

FIG. 5 shows a horizontal cross-sectional view of a ventilation device mounted on a cabinet; and

FIG. 6 shows a side view of a machine, mounted with two ventilation devices.

### DETAILED DESCRIPTION

An aspect of the present disclosure relates to a ventilation device for admitting air ventilation of a cabinet or machine housing and at the same time preventing liquid passing the ventilation device from outside to inside of the cabinet or machine housing, the ventilation device may comprise: a casing capable of being mounted in front of at least one cabinet opening of a cabinet, the casing may comprise at least one casing opening; a tube with a collar, where the tube is mounted on the casing and covering the at least one casing opening; and a cap covering the collar and leaving distance between the cap and the collar making it capable for air to pass between the cap and the collar.

When mounted on the cabinet, the casing is preferably located in front of at least one opening in the cabinet and which cabinet opening is for ventilation. The casing may comprise at least one casing opening and the tube, collar and cap are preferably located on the external side of the casing opening. In a preferred embodiment, the at least one opening in the cabinet and the at least one casing opening are located such that the at least one opening in the cabinet and the at least one casing opening do not overlap when observing the system from outside and towards the ventilation device.

The term ‘cabinet’ should be understood as any part of a machine or apparatus or system from where air can be directed into or out of. Cabinet may thus be a small part of a machine/apparatus/system or may be the basic housing of a machine/apparatus/system.

A tube may be mounted on the casing and covering the at least one casing opening. The tube is preferably mounted on the external side of the casing.

A collar is preferably located at the external end of the tube and bending outward in relation to a central axis of the tube. The collar may have an angle in relation to a central axis of the tube of from about 30′ to about 150, preferably the angle is of from about 70′ to about 110, such as about 90°.

The cap is preferably covering the collar such that the collar is not visible when the ventilation device is mounted on a cabinet and such that there may be a distance between the internal side of the cap and the collar as well as between the edge of the cap and the external side of the casing wall making it capable for air to pass between the cap and the collar and between the cap and the casing, respectively. Thus, the inner dimension of the cap is preferably larger than the outer dimension of the collar, hereby leaving a distance between the collar and the cap when the cap is connected to the collar such as connected by any distance means.

Preferably the cabinet opening and casing opening have equal opening area such that air easily can enter through both openings though different opening areas are also possible. The cabinet opening and especially the casing opening are preferably circular. The area i.e. space between the edge of the collar and the cap should preferably be such that smooth passage of air is possible and may thus be determined according to the cabinet opening area and/or to the amount of air being moved by any fan located in connection to a cabinet opening, however the area between the edge of the collar and the cap should preferably not be of a size too large such that water drops or droplets enter the ventilation device from outside in too large amounts and the area between the edge of the collar and the cap should preferably not be such that a counter-pressure is established and reducing effective ventilation.

The tube and cap are preferably circular in one dimension which is a design causing spreading and directing away any water directed towards the rounded parts during e.g. a washing process.

Preferably the casing of the ventilation device further comprises a front part with at least one casing opening; casing walls connected to the front part where the casing walls result in a distance between the cabinet wall and the front part when the casing is mounted on a cabinet; and optionally at least one cabinet connection area connected to the casing walls, where the at least one cabinet connection area is capable of being connected to a cabinet wall.

The front part of the casing is preferably positioned at a distance from the cabinet wall when the ventilation device is mounted on a cabinet, leaving space between the cabinet wall and the front part of the casing. The front part of the casing and the cabinet wall may be parallel. To mount the casing to a cabinet the casing may comprise at least one cabinet connection area, which may include apertures suitable for connecting the casing to a cabinet. The apertures may e.g. be screw holes suitable for mounting the casing to a cabinet. Other possibilities of connecting the ventilation device to a cabinet may also be used, however, is a water tight connection is preferred.

In the ventilation device, the casing may further comprise one or more liquid outlets in at least one casing wall. The liquid outlet may be located at the bottom part of the casing wall when the casing is mounted on a cabinet. Such a liquid outlet may be one or more small apertures in the casing wall. A suitable number of small apertures in the bottom part of the casing may be present, such that any water drops which may be present inside of the ventilation device may be drained off through the at least one liquid outlet.

In the ventilation device, at least one cover may be located inside of the casing and covering the liquid outlet. Here ‘covering’ means separating a volume inside the casing and between a liquid outlet and a volume above the cover.

The ventilation may further comprise at least one distance means connected to the collar at an external side of the collar. The at least one distance means may be connected to a cap when a cap is mounted as part of the ventilation device. The distance means may secure a space is left between the inside of the cap and the collar hereby permitting air passing in this space.

Preferably the casing is constructed of a material with is liquid tight and/or can withstand high-pressure washing and/or can withstand washing with aggressive detergents and/or can withstand washing with liquid at high temperatures. Such a material may be a metal, such as steel, preferably stainless steel. The tube, collar and cap may also be constructed of a material with is liquid tight, such as steel, preferably stainless steel.

In a preferred embodiment, the ventilation device is liquid tight all over except for the described spaces which should leave room for air passage into or out of a cabinet i.e. non-liquid tight space may be present at the cabinet opening, at the space between the cabinet wall and the casing of the ventilation device, inside the tube, between the collar and the cap, and at the liquid outlet of the casing wall. Preferably the ventilation device is connected to a cabinet in a liquid tight manner e.g. including a sealing compound securing a liquid tight connection.

At least one fan may be located at the internal side of the casing, such as between the cabinet wall and the casing e.g. covering the cabinet opening and/or a fan may be located within the cabinet just inside the cabinet opening.

A ventilation device for admitting air ventilation of a cabinet and preventing liquid passing from the outside to the inside of the cabinet may thus comprise: a casing capable of being mounted on the external side of a cabinet wall, where the cabinet wall has one or more cabinet openings, which casing may comprise: a front part with at least one casing opening; casing walls connected to the front part, where the casing walls result in a distance between the cabinet wall and the front part, when the casing is mounted on a cabinet; optionally at least one cabinet connection area connected to the casing walls, where the cabinet connection area is capable of being connected to the cabinet wall; at least one liquid outlet in at least one casing wall, where the liquid outlet is located in the bottom part of the casing wall, when the casing is mounted on a cabinet; at least one cover located inside of the casing and covering the liquid outlet; a tube with a collar, where the tube is connected to the external side of the casing and covering the at least one casing opening; at least one distance means connected to the collar at an external side of the collar; a cap connected to the at least one distance means where the cap is covering the collar and leaving distance between the cap and the collar making it capable for air to pass between the cap and the collar.

The ventilation device described herein is preferably mounted on a cabinet with at least one cabinet opening such that the casing opening is not located directly in front of the at least one cabinet opening. Preferably the front part of the ventilation device has a dimension making it possible to mount the ventilation device such that the casing opening is located in one side or end of the ventilation device and the cabinet opening is located behind the other side or end of the ventilation device when observed from inside or outside of the cabinet.

Air moving through a ventilation device as described herein and into a cabinet may enter the ventilation device at the edge of the collar, follow the internal side of the cap into the tube, through the casing opening, passing the volume between the front part of the casing and the cabinet and enter through the cabinet opening into the cabinet. When entering the cabinet opening the air may also enter a fan such as just prior to entering the cabinet opening or just after passing the cabinet opening depending on the location of any possible fan. Air moving out of a cabinet moves in the opposite direction. The air movement directions are indicated in one of the figures.

The dimensions of the items of the ventilation device may be any suitable for ventilation of a cabinet and avoiding water passing into the cabinet. The dimensions of a ventilation device mounted on a cabinet and oriented with the longest wall of the casing horizontal may be:

Length of casing: 440 mm

Height of casing: 233.2 mm

Distance from bottom of casing to centre of casing opening: 96 mm

Distance from side of casing to centre of casing opening: 98 mm

Diameter of case opening: 82 mm

Thickness of casing=width of casing wall: 51 mm

Diameter of water stopper 82.6 mm

Outer diameter of collar: 138 mm

Diameter of cap: 168 mm

Distance from edge of collar to wall of cap: 13 mm

Distance from collar to water stopper 20 mm

Distance from water stopper to inside of cap: 6.5 mm

Distance between casing front and edge of cap: 21 mm

Height of cap: 49 mm

Distance from casing front to collar 40 mm

Distance from centre of casing opening to centre of cabinet opening:

220 mm

Thickness of metal making up the ventilation device: 1.5 mm

Other dimensions than those just described may also be suitable.

The dimensions of the ventilation device and of the cabinet opening may be determined in relation to the amounts of electrical components of a cabinet and thus to the amount of produced heat within the cabinet i.e. to the required degree of ventilation. The dimensions of the ventilation device may also be determined, taking into account any air flow produced by a fan, i.e. whether a fan is small or large, and/or weak or powerful.

In a preferred embodiment, the ventilation device as described herein does not comprise a filter. However, for ventilation devices used for letting air passing into a cabinet a dust filter may be connected to the ventilation device. A dust filter may be located in the volume between the cabinet wall and the front part of the casing, and the dust filter is preferably located as close to the cabinet opening as possible, thereby reducing the risk of water or moist reaching the dust filter. A fan may also include a dust filter.

Further characteristics of the ventilation device may be evident from the figures and/or from the description of the figures, such characteristics may e.g. be in relation of size dimensions and/or dimensions of volumes of empty space leaving room for air transport.

Preferably the ventilation device is mounted on a cabinet such that the front part of the casing is vertical. The ventilation device may be mounted with the cabinet opening and casing opening side by side or the one above the other i.e. cabinet opening above casing opening or the opposite.

Another aspect of the present disclosure relates to a machine with a ventilation device as described herein. Preferably the machine is an industrial machine/apparatus, such as a food producing machine/apparatus and/or food controlling machine/apparatus and/or food analysing machine/apparatus.

In a preferred embodiment, a cabinet comprises at least two of the ventilation devices as described herein. At least one of these ventilation devices is preferable for direction air out of the cabinet and at least one other of these ventilation devices is preferable for direction air into the cabinet. Here ‘direction’ may be by passive diffusion of air out of or into a cabinet, or may be by active air moving such as by a fan driving an air flow. A fan may be located inside of or in connection to one or more of the at least two ventilation devices of a cabinet such that air may be directed into or out of the cabinet depending on the airflow direction produced by the fan.

At companies handling unpacked food or parts thereof and at companies producing food specific hygienic requirements are present. Such hygienic requirements may include thorough cleaning of the machines/apparatus e.g. with high-pressure washing and/or washing with aggressive detergents and/or washing with liquid at high temperatures. Such machines/apparatus may still need ventilation during use to reduce or avoid the risk of overheating of internal located electronic components. The ventilation device described herein can be used to cool such machines/apparatus by directing heat out of the cabinet of the machines/apparatus and when the machines/apparatus is washed washing liquid entering the machine/apparatus can to a high degree be prevented and any liquid entering or being generated within the ventilation device can be directed out of the ventilation device such that the liquid does not damage any electronic components within the ventilation device or within the machine/apparatus.

A further aspect of the present disclosure relates to use of the ventilation device as described herein for cooling a machine or a cabinet or an apparatus. As described above such machine, apparatus or cabinet is preferably for food production.

The ventilation device described herein offer a cost-effective solution to recurrent ventilation problems such as in food industry machinery and measuring cabinets producing excess heat which may be critical to internal machine mechanical and electronic components. The ventilation device may be used to maintaining temperatures below a specific degree to avoid damage to the internal machine mechanical and electronic components.

The ventilation device as described herein may be used for: passive ventilation; or active ventilation with at least one fan blowing air out of one ventilation device and passive inlet of air from at least one other ventilation device; or active ventilation with a fan blowing air out of at least one ventilation device and active inlet of air from at least one other fan sucking ambient air through the ventilation device from the outside of the cabinet or from another room or from outside the building.

The purpose when using the ventilation devices described herein is to ventilate internally in a cabinet preferably with the use of ambient air to reduce internal temperatures below critical limits for internal air temperature around components inside the cabinet. This may be realized with a ventilation device described herein and permitting a sufficient airflow into and out of the cabinet to allow temperature reduction, while at the same time during any wet cleaning processes limiting the intake of moist air to a minimum, and preventing water droplets or flushes of water from e.g. water cleaning systems based on high-pressure high-volume systems using cascades of water.

In a cleaning process, any fans being present in or close to any ventilation devices of a cabinet is preferably inactive to limit any moist air inflow near the ventilation holes to a minimum.

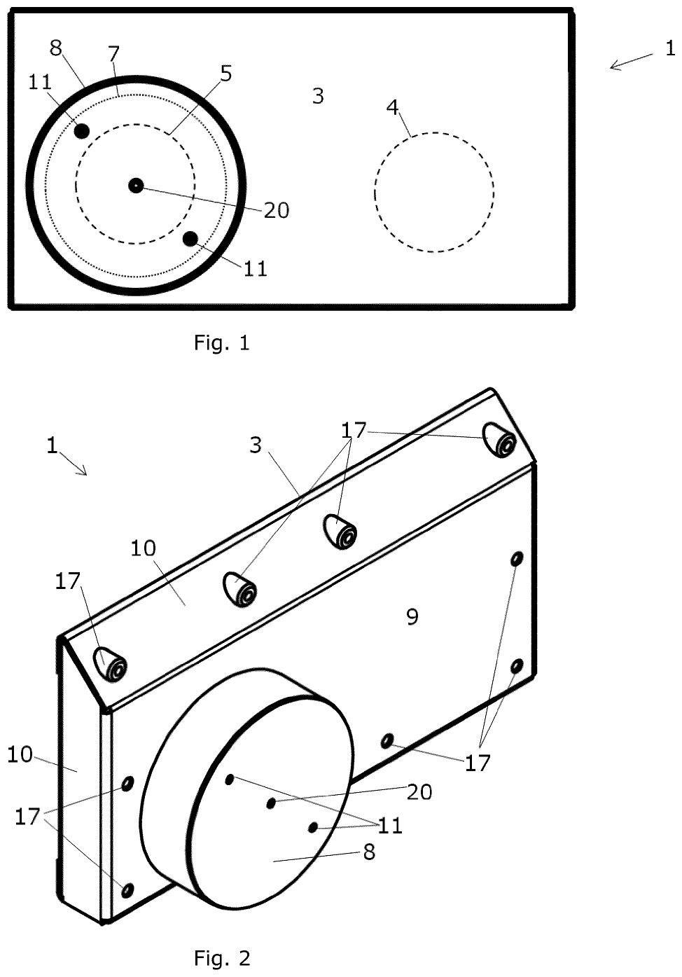

FIG. 1 illustrates the front of a ventilation device (1) with a casing (3) and a cap (8) mounted on the ventilation device (1). Illustrated with dotted lines is also the location of a cabinet opening (4) behind the casing (3) and a casing opening (5) behind the cap (8). The edge of a collar (7) behind the cap (8) is also illustrated as a dotted line. Possible locations of cap fastening means (11) securing the cap to distance means are indicated.

FIG. 2 is a perspective drawing of a ventilation device (1). The casing (3) has a front part (9) and casing walls (10). The casing (3) can be fastened to a cabinet by fastening means (17). In front of the casing (3) is the cap (8) located, which is secured by cap fastening means (11). In the centre of the cap (8) water stop fastening means (20) is indicated, which is connecting a water stop to the inside of the cap (8).

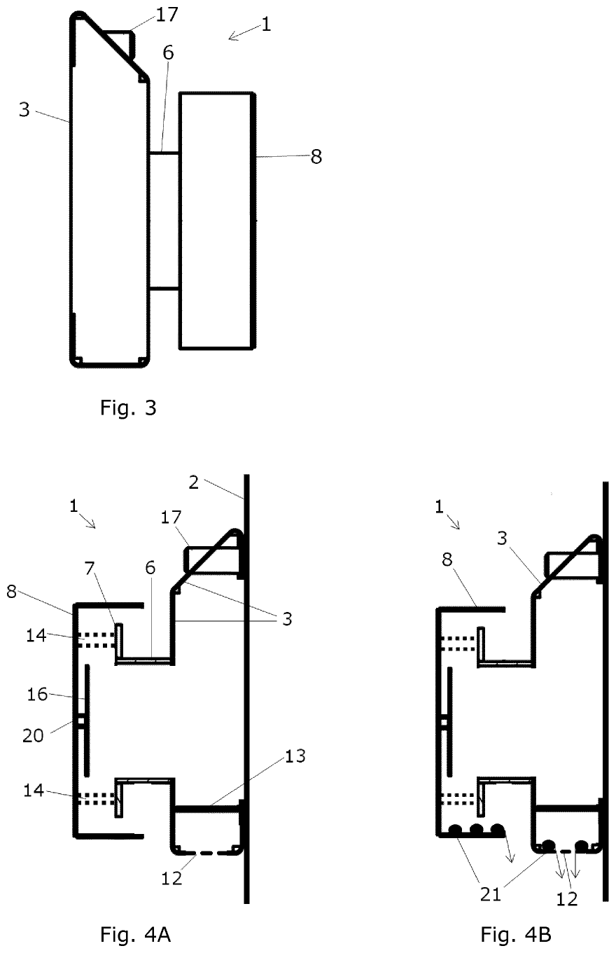

FIG. 3 is a side-view of a ventilation device (1). The casing (3) can be mounted on a cabinet (not illustrated) by fastening means (17). A tube (6) is connected to the casing (3) and a cap (8) covers part of the tube (6).

FIG. 4A is a vertical cross-sectional view of a ventilation device (1) mounted on a cabinet (2). The cross section is made through the tube (6). The casing (3) is mounted on a cabinet (2) by fastening means (17). Extending from the casing (3) is a tube (6), which holds a collar (7). A cap (8) is connected to the collar (7) by distance means (14) here illustrated with a dotted line, as air can pass by the distance means (14). On the internal side of the cap (8) a water stopper (16) is illustrated though the water stopper (16) need not be present. A water stopper fastening means (20) secure the water stopper (16) to the cap (8). In the bottom part of the casing a liquid outlet (12) is located with a cover (13) located above. No cabinet opening is indicated as the casing opening and the cabinet opening preferably is in different planes as indicated in FIG. 1.

FIG. 4B is similar to FIG. 4A, and shows how water drops (21) captured by the ventilation device (1) will be collected at the bottom part of the cap (8) and/or of the casing (3) and the water drops will be led out of the ventilation device (1) as indicated by the arrows i.e. from the lowest part of the cap (8) and/or out through the liquid outlet (12) of the casing (3).

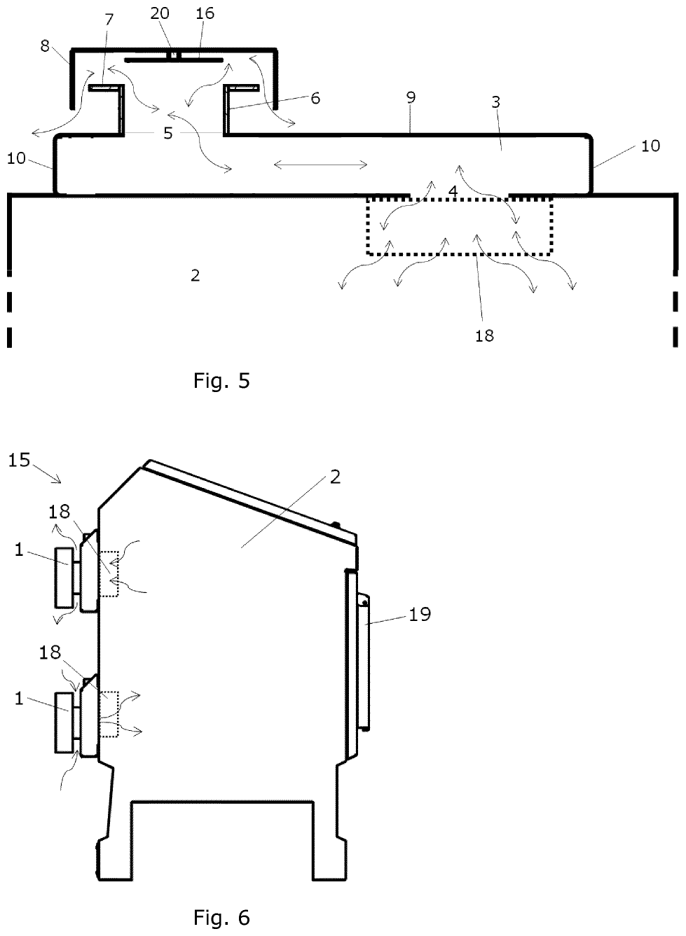

FIG. 5 is a horizontal cross-sectional view of a ventilation device mounted on a cabinet (2). The cabinet (2) has a cabinet opening (4) which is covered by the front part (9) of the casing (3). At a distance from the cabinet opening (4) the ventilation device has a casing opening (5) covered by a tube (6) with a collar (7), and also covered by a cap (8). Optionally a water stopper (16) can be mounted on the internal side of the cap (8) by a water stopper fastening means (20). The double-arrowed arrows indicate the directions where air can be directed one way or the other through the ventilation device. When in use, air is normally only directed on way i.e. out of or into the cabinet (2). Illustrated is also casing walls (10) and a possible location of a fan (18). The fan (18) may also be located under the casing (3) i.e. inside the ventilation device and outside of the cabinet (2).

FIG. 6 is a side view of a machine (15) with two ventilation devices (1) mounted one above the other on a cabinet (2), here shown on a cabinet wall opposite of a display and/or control panel (19). A fan (18) is indicated for each ventilation device (1), and arrows indicate the possible overall direction of air into and out of the cabinet. Though the machine (15) is illustrated with one fan (18) at each ventilation device (1), machines may be constructed with only a fan at one ventilation device or without any fan at the ventilation devices.

### Example

The ventilation device as described herein and as shown in the FIGS. 1 to 6 has been tested with industrial type high pressure cleaning tools providing water jet of 24 Bar and with an amount of 30 L/min.

With close-up nozzles pointed near the ventilation device (from about 1-2 cm and various distances up to e.g. 50 cm) and with multiple orientations and angles of the water jet to the ventilation device and variable durations of the washing process, thus resembling traditional cleaning processes in the food industry, it has been tested and demonstrated that the ventilation device as described herein allowed the following results:
1. No flow of water entering the cabinet through the cabinet openings;
2. No mist or water drops or sprinkles of water entering the cabinet through the cabinet openings;

Test of airflow and moisture content of incoming air associated with a prolonged cleaning process was also tested using the high-pressure cleaning process and by using an operator evaluation with: operator face inside of a cabinet wall with a ventilation device and close to the cabinet opening checking for visible moist and sprinkles entering the cabinet through the cabinet opening, and feeling on facial skin any potential moist air entering the cabinet through the cabinet opening; and operator hand inside of a cabinet wall with a ventilation device and using the backside of the hand covering the cabinet opening for feeling on the skin any air flow and potential moist air entering the cabinet through the cabinet opening.

The results hereof were:
1. While it was observed that the cleaning process did provide an active inflow of air into the cabinet through the cabinet opening, it was not associated with a very moist feeling on the face or on the hand, nor was any visible flow of water near the cabinet opening apparent
2. No detergent was visible inside the cabinet opening i.e. detergent did not pass the ventilation device

Tests were performed using food industry cleaning processes and detergents including foam. These tests showed no visible foam or detergents near the air inlet on the outside of the cabinet wall.

### LIST OF REFERENCE SIGNS

In the figures, identical structures, elements or parts that appear in more than one figure are generally labelled with the same numeral in all the figures in which they appear:
1. Ventilation device;
2. Cabinet;
3. Casing;
4. Cabinet opening;
5. Casing opening;
6. Tube;
7. Collar;
8. Cap;
9. Front part of casing;
10. Casing wall;
11. Cap fastening means;
12. Liquid outlet of casing;
13. Cover;
14. Distance means;
15. Machine;
16. Water stopper;
17. Fastening means;
18. Fan;
19. Display and/or control panel;
20. Water stopper fastening means;
21. Airdrops captured by the ventilation device;

What is claimed is:

1. A ventilation device for admitting air ventilation of a cabinet and preventing liquid passing from outside to inside of said cabinet, the (2), which ventilation device comprising:
a casing configured to be mounted in front of a cabinet opening of a cabinet, the casing comprising one or more casing openings;
a tube comprising a collar, wherein said tube is mounted on the casing, and covering said one or more casing openings; and
a cap covering said collar, wherein a space between said cap and said collar is configured to pass air between said cap and said collar.

2. The ventilation device of claim 1, wherein said casing further comprises:
a front part comprising with at least one casing opening of the one or more casing openings;
a plurality of casing walls connected to the front part such that the casing walls form a gap between the cabinet wall and the front part when the casing is mounted on the cabinet.

3. The ventilation device of claim 1, wherein said casing further comprises at least one liquid outlet in at least one casing wall, and wherein the at least one liquid outlet is located in a bottom part of the casing wall when the casing is mounted on the cabinet.

4. The ventilation device of claim 3, further comprising at least one cover located inside of said casing and at least partly covering the liquid outlet.

5. The ventilation device of claim 1, further comprising at least one spacer connected to the collar at an external side of said collar and to the cap at an internal side of said cap.

6. The ventilation device of claim 1, wherein said casing is constructed of a material which is liquid tight.

7. The ventilation device of claim 1, wherein said tube, said collar, and said cap are constructed of a material with is liquid tight.

8. The ventilation device of claim 1, further comprising at least one fan located at an internal side of said casing.

9. A machine comprising at least one ventilation device according to claim 1.

10. A method, comprising:
mounting a casing of a ventilation device in front of a cabinet opening of a cabinet, wherein the casing comprises one or more casing openings, a tube, and a cap, wherein the tube comprises a collar and is mounted on the casing and covering said one or more casing openings, and wherein the cap covers said collar of said tube; and
cooling said cabinet by passing air through a space between said cap and said collar.
